(19) United States
(12) Patent Application Publication
(10) Pub. No.: US 2016/0111313 A1
(43) Pub. Date: Apr. 21, 2016

(54) APPARATUS FOR THE VACUUM TREATMENT OF SUBSTRATES

(71) Applicant: LEYBOLD OPTICS GMBH, Alzenau (DE)

(72) Inventors: Harro HAGEDORN, Frankfurt am Main (DE); Jürgen PISTNER, Alzenau-Michelbach (DE); Thomas VOGT, Grosskrotzenburg (DE); Alexander MULLER, Hasselroth (DE)

(73) Assignee: Leybold Optics GMBH, Alzenau (DE)

(21) Appl. No.: 14/782,354

(22) PCT Filed: Mar. 26, 2014
(86) PCT No.: PCT/EP2014/056090

§ 371 Date: Dec. 22, 2015

(30) Foreign Application Priority Data
Apr. 5, 2013 (DE) 10 2013 005 765.5
Apr. 8, 2013 (DE) 10 2013 005 868.6

(51) Int. Cl. H01L 21/683; C23C 14/34; C23C 14/56; H01L 21/677

(52) U.S. Cl. CPC H01L 21/683; H01L 21/67742; C23C 14/34; C23C 14/568

(57) ABSTRACT

The invention relates to an apparatus for the vacuum treatment of substrates (130), comprising a vacuum chamber (1) having a plasma device (160) of a process chamber (110) and a holding device (135) for substrates (130), which is arranged in the process chamber (110), underneath the plasma device, wherein the process chamber (110) comprises an upper subsection (105a) having a side wall (106a) and a lower subsection (105b) having a side wall (106b), and the upper subsection (105a) and the lower subsection (105b) can be moved vertically relative to each other. According to the invention between the side wall (106a) of the upper subsection (105a) and the side wall (106b) of the lower subsection (105b), a lower flow path (105c) extends between the inner region (140) of the process chamber (110) and the inner region (1a) of the vacuum chamber (1) that is arranged outside the upper subsection (105a). Furthermore, between an upper edge region (107) of the upper subsection (105a) and a sealing element (109) arranged in an upper part of the inner region (1a) of the vacuum chamber (1), an upper flow path (190) is provided between the inner region (140) of the process chamber (110) and the inner region (1a) of the vacuum chamber (1) that is arranged outside the upper subsection (105a), wherein the upper subsection (105a) can be moved relative to the vacuum chamber (1) into a lower position, in which the upper flow path (190) is opened, the upper subsection (105a) can be moved relative to the vacuum chamber (1) into an upper position, in which the upper flow path (190) is closed.

### TECHNICAL FIELD

The invention relates to an apparatus for the vacuum treatment of substrates.

### BACKGROUND

In conventional vacuum coating apparatuses the process chamber, in which the actual vacuum coating is performed by means of plasma, is shielded by means of fixedly mounted shields in order to avoid parasitic coatings with respect to the remaining vacuum chamber. Fixedly mounted shields, however, may impair the accessibility of the process chamber.

A plasma process apparatus is already known from document US 2011/0089023 A1 which comprises a chamber, a substrate platform, an electrode for generating plasma within the chamber and a shielding device, which surrounds a plasma chamber between electrode and substrate platform. The shielding device comprises a main part and a separate part, wherein the main part and the separate part each have an inner portion and an outer portion, wherein the outer portion is formed in each case as a gas conductance device. The inner portion of the main part and the inner portion of the separate part are shaped such that they are not in contact with one another.

A coating system having variable gas conductance values for a process chamber for coating integrated circuits is also known from U.S. Pat. No. 7,318,869 B. A movable shield surrounds a pedestal, wherein the shield has a structure that generates a variable opening in the chamber when the shield assumes different positions along a linear path. The movable shield comprises a first apparatus region, which forms a first flow path, and a second apparatus region, which forms a second flow path. The flow paths have variable conductance values. An upper flow path is formed by the inner surface of the shield and the outer surface of the process chamber cover. A lower flow path is formed by a shadow ring and the lower part of the shield together with a shadow ring mount. Due to the change in the relative positions of the shield and the shadow ring, the gas conductance values of the process chamber can be modulated. In a loading position the shield assumes an upper position relative to the pedestal. In a processing position the shield assumes a middle position. In a cleaning position the shield and the shadow ring mount are in a lower position, wherein the shadow ring rests on a shelf.

A shut-off valve for a vacuum apparatus for separating a process chamber and an electron beam canon of the vacuum apparatus is known from DE 11 2006 003 294 T5. A valve housing with openings, which are provided opposite one another on side walls, and a valve body for opening/closing the openings are also provided. A cylindrical and movable shield can be introduced via an opening on the side of the process chamber into the valve housing when the valve is opened. Therebetween, the shield is freely movable to and fro. The interior of the movable shield and the interior of the valve housing can be atmospherically separated from one another.

A removable shield arrangement for a semiconductor process system is also known from U.S. Pat. No. 6,730,174 B2, having an upper adapter arrangement, at least one shield unit, which is fixed at the upper end of the upper adapter arrangement, a cover ring and an isolator device, wherein the upper adapter arrangement, the at least one shield unit, the cover ring and the isolator can be removed simultaneously as a unit.

### BRIEF SUMMARY

The invention provides an apparatus for the vacuum treatment of substrates, with which the vacuum chamber can be shielded with respect to a treatment process taking place in the process chamber in order to avoid parasitic coatings of the vacuum chamber, wherein at the same time the interior of the process chamber has good accessibility and the pumping capacity for the inner region of the process chamber is adjustable.

The apparatus according to the invention for the vacuum treatment of substrates, comprising a vacuum chamber having a process chamber and a plasma device and a holding device for substrates which is arranged in the process chamber below the plasma device, is characterized in that
the process chamber comprises an upper sub-portion having side walls and a lower sub-portion having side walls
the upper sub-portion and the lower sub-portion are movable relative to one another
between the side wall of the upper sub-portion and the side wall of the lower sub-portion, a lower flow path is provided between the inner region of the process chamber and the inner region of the vacuum chamber arranged outside the upper sub-portion
between an upper edge region of the upper sub-portion and a sealing element arranged in an upper part of the inner region of the vacuum chamber, an upper flow path is provided between the inner region of the process chamber and the inner region of the vacuum chamber arranged outside the upper sub-portion
the upper sub-portion is movable relative to the vacuum chamber into a lower position, in which the upper flow path is open
the upper sub-portion is movable relative to the vacuum chamber into an upper position, in which the upper flow path is closed.

The upper sub-portion of the process chamber can shield the interior of the vacuum chamber against parasitic coating during the vacuum chamber without impairing the accessibility of the interior of the process chamber for pumping purposes and substrate handling.

Because between the side wall of the upper sub-portion and side wall of the lower sub-portion there is provided a lower flow path between the inner region of the process chamber and the inner region of the vacuum chamber arranged outside the upper sub-portion, the lower flow path can be produced in a structurally particularly simple manner. Because between an upper edge region of the upper sub-portion and a sealing element arranged in an upper part of the inner region of the vacuum chamber there is provided an upper flow path between the inner region of the process chamber and the inner region of the vacuum chamber arranged outside the upper sub-portion, the upper flow path likewise is produced in a particularly structurally simple manner. Here, the upper flow path is advantageously also open if the upper sub-portion is moved relative to the vacuum chamber into a lower position. It is also advantageous that the upper flow path is closed if the upper sub-portion is moved relative to the vacuum chamber into an upper position. Here, it is advantageous if, when the upper sub-portion relative to the vacuum chamber is in the upper position, the process chamber is sealed optically tightly with respect to the inner region of the vacuum chamber arranged outside the upper sub-portion and the lower sub-portion. A parasitic coating of the inner region of the vacuum chamber is thus reliably prevented, wherein at the same time the process chamber can be supplied with process gases via the lower flow path.

The substrates may be in particular spectacle lenses or the like, which are channeled into the vacuum chamber as a batch, are vacuum-treated, and channeled out again.

The lower sub-portion can be formed in an advantageous embodiment as an insert component which is inserted or can be inserted into a recess in the base region of the vacuum chamber.

In a further embodiment of the invention the lower sub-portion is formed by a recess in the base of the vacuum chamber. Material can be saved as a result, however the coating of this region of the vacuum chamber must be accepted.

In a further embodiment of the invention the side wall of the upper sub-portion is formed as an upper cylinder ring, whereby the upper flow path and the lower flow path can be produced in a structurally very simple manner.

In particular the upper cylinder ring may have an outer diameter which is slightly smaller than the inner diameter of the lower sub-portion, and here an overlapping of the side wall of the upper sub-portion and the side wall of the lower sub-portion may be provided, such that a gap is created between parts of the side wall of the upper sub-portion and parts of the side wall of the lower sub-portion. The lower flow path runs here through the gap formed between the side walls of the upper sub-portion and the lower sub-portion. A conductance value of the lower flow path can be fixed by the gap space. It may also be advantageous for an overlapping to still be provided when the upper sub-portion assumes the upper position. The upper flow path is then closed whilst the lower flow path is open.

The side wall of the lower sub-portion may also be formed as a lower cylinder ring.

In another embodiment the upper cylinder ring has an inner diameter which is slightly greater than an outer diameter of the lower cylinder ring.

In a further embodiment the holding device is formed in the process chamber so as to be movable relative to the vacuum chamber. The distance of the substrates from the plasma device can thus be changed without changing the conductance values of the flow paths, whereby parameters of the vacuum treatment of the substrates, such as ion energies of the plasma on the substrate surface, can be influenced separately from the conductance values.

In a further embodiment of the invention the holding device in the upper position can be loaded with substrates via the substrate channeling device. In this case the upper sub-portion is brought into a lower position.

In a further embodiment of the invention the holding device has a baseplate which forms an intermediate base region in the process chamber, such that the chamber size is variable. Any elements present of a lifting device by means of which the holding device can be moved are thus protected against parasitic coating.

In a further embodiment of the invention the side wall of the upper sub-portion and/or the side wall of the lower sub-portion are manufactured at least in part from a conductive material and may act as anode or part anode.

In a further embodiment of the invention the upper sub-portion is electrically insulated with respect to the vacuum chamber, whereby a further degree of freedom is obtained for setting the potential conditions within the process chamber.

In a further embodiment of the invention the lower sub-portion is electrically insulated with respect to the vacuum chamber, whereby a further degree of freedom is obtained for setting the potential conditions within the process chamber.

In a further embodiment of the invention the upper sub-portion is electrically connected to the vacuum chamber, whereby a further degree of freedom is obtained for setting the potential conditions within the process chamber.

In a further embodiment of the invention the lower sub-portion is electrically connected to the vacuum chamber, whereby a further degree of freedom is obtained for setting the potential conditions within the process chamber.

In a further embodiment of the invention at least the base plate of the holding device comprises an electrically conductive material and is electrically insulated with respect to the vacuum chamber, the upper sub-portion or the lower sub-portion, whereby a further degree of freedom is obtained for setting the potential conditions within the process chamber. In a further embodiment the base plate is manufactured from an electrically conductive material and is electrically connected to the vacuum chamber, the upper sub-portion, or the lower sub-portion.

In a further embodiment of the invention the lower sub-portion has a base part, which is connected to the side wall of the lower sub-portion. The lower sub-portion may advantageously be inserted as a whole into a recess in the base of the vacuum chamber and also removed again.

In a further embodiment of the invention the channeling device comprises a channeling-in and channeling-out chamber comprising a provision region for providing substrates, wherein a transport path for transporting substrates leads from the provision region to the holding device and from the holding device to the provision region. The transport is thus barrier-free when the channel is open.

In a further embodiment of the invention a pivot plate is provided for transport along the transport path between the provision region and holding device and can be pivoted about a pivot axis between the provision region and holding device, whereby a good utilization of space can be achieved in a structurally simple manner.

In a further embodiment of the invention the pivot plate has a support structure with support means for substrates, such that the substrates are securely guided during the transport.

In a further embodiment of the invention the holding device has substrate holding elements, wherein the pivot plate in the region of the holding structure has at least one recess, which is associated with the substrate holding elements and allows the pivot plate to pivot into the region of the substrate holding elements without any impairment of movement. The at least one recess makes it possible to position the substrates directly in the region of the holding device, whilst they are still resting on the support structure of the pivot plate.

In a further embodiment of the invention the substrate holding elements are height-adjustable in order to receive the substrates and to transfer the substrates. The substrates are then securely received by the substrate holding elements during the plasma treatment.

In a further embodiment of the invention the holding device is formed as a coating rotor having a main axis of rotation, whereby a uniformity of a coating is increased.

In a further embodiment of the invention the plasma source is formed as a sputter cathode, electron beam evaporator or plasma polymerization source.

### BRIEF DESCRIPTION OF THE DRAWINGS

Further advantages will emerge from the following description with use of drawings. Exemplary embodiments of the invention are illustrated in the drawings. The drawings, the description and the claims contain numerous features in combination. A person skilled in the art will expediently consider the features individually and combine them to form meaningful further combinations.

In the drawings, by way of example:

FIG. 1 shows a schematic illustration of an apparatus according to the invention having a process chamber having an upper and a lower sub-portion;

FIG. 2 shows a simplified schematic illustration of the apparatus in FIG. 1 without the lower sub-portion of the process chamber;

FIG. 3 shows a schematic illustration of an apparatus according to the invention having a provision device for substrates;

FIG. 4 shows a schematic illustration of an apparatus according to FIG. 3 in a horizontal section.

### DETAILED DESCRIPTION

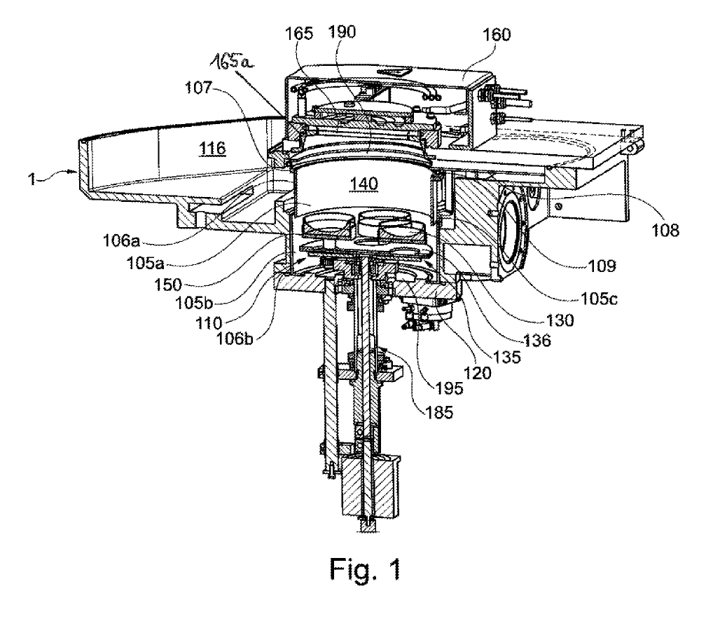

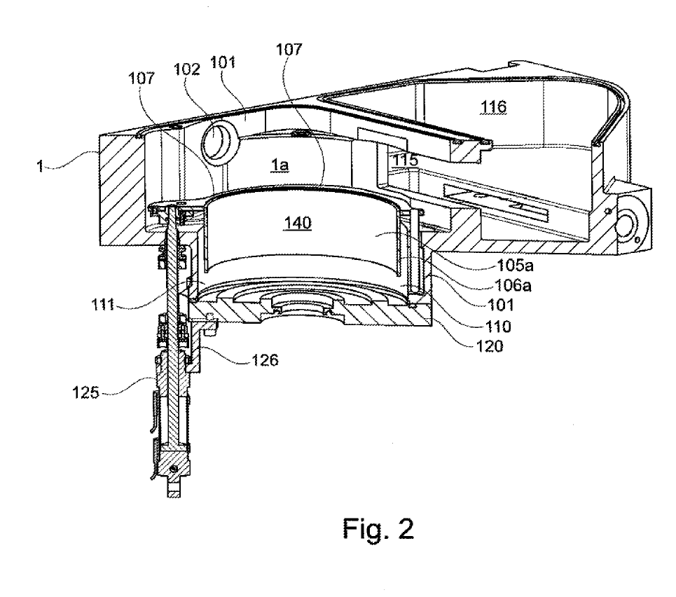

FIGS. 1 and 2 show an apparatus according to the invention having a vacuum chamber 1 having a substrate channeling device 116 and a plasma device which is arranged on an upper cover 108 of the vacuum chamber 1, said cover having a corresponding opening. The plasma device formed in this embodiment as a cathode device 160 in particular comprises a sputter target 165. It goes without saying that a differently formed plasma device is also included by the invention.

As is illustrated in FIG. 2, the substrate channeling device 116 in particular comprises a channeling opening 115, which is arranged in the chamber wall 101 of the vacuum chamber 1. A pump opening 102 is also arranged in the chamber wall 101. It goes without saying that further openings may also be provided in the chamber wall 101, should this be expedient for the evacuation, ventilation or operation of the vacuum chamber 1.

A process chamber 110 is arranged in the inner region 1a of the vacuum chamber 1 and comprises an upper sub-portion 105a having a side wall 106a and a lower sub-portion 105b having a side wall 106b. An upper side of the process chamber 110 comprises the sputter target 165 and a target mount 165a. The side walls 106a, 106b are manufactured at least in part from a conductive material, for example stainless steel. The side walls 106a and 106b are formed in the shape of a cylinder ring. The lower sub-portion 105b is arranged fixedly in a recess 152 in the base region 120 of the vacuum chamber 1 and has a base part 195, which is connected to the side wall 106b.

The process chamber 110 has an inner region 140, in which a vacuum treatment of substrates 130 mounted in a substrate mount 150 can take place. The vacuum treatment is preferably a coating of surfaces of the substrates 130 by means of a sputter plasma. It goes without saying that other vacuum treatments, in particular pre-treatments or cleaning processes, may also take place in the process chamber 110.

In the inner region 140 of the process chamber, there is arranged a holding device 135 for substrates 130. By means of the cathode device 160 arranged above the holding device 135, the substrates 130 can be coated, for example. The holding device 135 comprises a base plate 136, of which the edges are arranged at a short distance from the side wall 106b and form an intermediate base region in the process chamber. In this way, a process space is formed within the process chamber by means of the side walls 106a and 106b and the base plate 136.

The receiving device 135 is connected via a vacuum feedthrough to a lifting device 185, by means of which a vertical movement of the holding device 135 can be performed within the process chamber 110.

The upper sub-portion 105a has an upper edge 107, which can be pressed against a sealing element 109 in the upper part of the vacuum chamber when the upper sub-portion 105a is located in an upper position relative to the vacuum chamber 1. The sealing element 109 may be for example a ring seal mounted in an opening in the upper cover 108, the shape of said ring seal being adapted to the upper edge 107. An upper flow path 190 extending between the upper edge region 107 and the sealing element 109 is then closed when the upper edge region 107 is pressed against the sealing element 109.

The upper sub-portion 105a can be moved relative to the vacuum chamber 1 into lower positions, in which the upper flow path 190 is open. As is illustrated in FIG. 2, the edge region 107 may then be positioned such that there is a good accessibility of the inner region 140 via the channeling opening 115, for example in order to load substrates.

The upper sub-portion 105a is connected via a vacuum feedthrough to a lifting device 125, which is fastened by means of a mounting element 126 for example to the underside of the vacuum chamber 1 in the base region. The upper sub-portion can be vertically moved by means of the lifting device 125. A particularly simple draining or venting of the process chamber 110 is possible via the pump opening 102 in a lower position of the upper sub-portion 105a.

The upper sub-portion 105a and/or the lower sub-portion 105b can be electrically insulated with respect to the vacuum chamber 1. The upper sub-portion 105a and/or the lower sub-portion 105b may also be electrically connected to the vacuum chamber. The upper sub-portion 105a and/or the lower sub-portion 105b may also be placed at a predefined or floating electrical potential with respect to the vacuum chamber 1. In particular, the upper side wall 106a and/or the lower side wall 106b may be electrically insulated with respect to the vacuum chamber 1. The upper side wall 106a and/or the lower side wall 106b may also be electrically connected to the vacuum chamber 1. The holding device 135 or the base plate 136 may also be electrically insulated with respect to the vacuum chamber 1, the upper sub-portion 105a and/or the lower sub-portion 105b. The holding device 135 or the base plate 136 may also be electrically connected to the vacuum chamber 1, the upper sub-portion 105a and/or the lower sub-portion 105b. The holding device 135 or the base plate 136 may also be placed at a predefined or floating electrical potential with respect to the vacuum chamber 1.

During a vacuum treatment, the upper sub-portion 105a is preferably brought into an upper position, such that the inner region la of the vacuum chamber 1 is not subject to any parasitic coating.

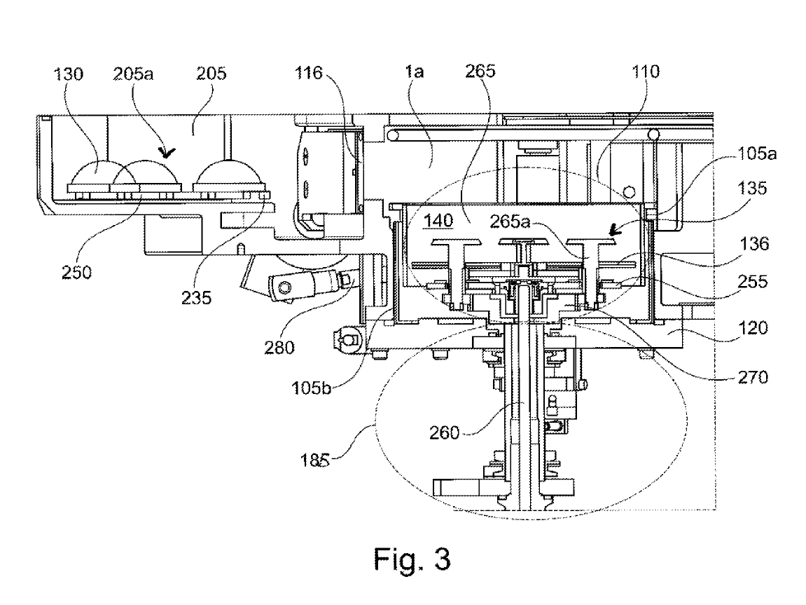

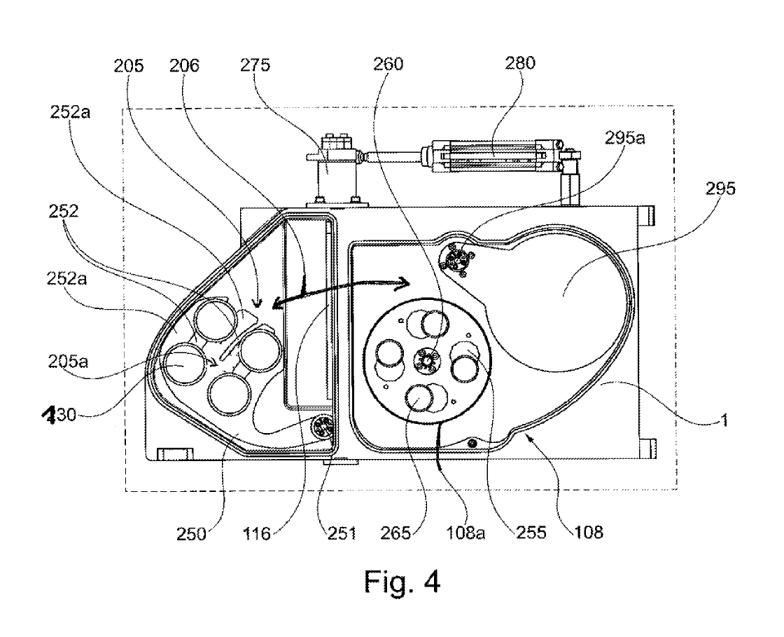

FIGS. 3 and 4 in a schematic illustration show an embodiment of an apparatus according to the invention having a channeling device 116 comprising a channeling-in and channeling-out chamber 205. A provision region 205a for providing substrates 130 is arranged in the channeling-in and channeling-out chamber 205. A transport path 206, indicated by an arrow, leads from the provision region 205a to the receiving device 135 and from the receiving device 135 to the provision region 205a. The transport path 206 leads through the opening of the channeling device 116.

In FIG. 4 a cover screen 295 can be seen, which is movable about a pivot axis 295a. The cover screen is matched in terms of shape to a recess 108a in the cover 108 and makes it possible to shield the interior la of the vacuum chamber with respect to the plasma device 160. A conditioning, for example of a sputter cathode, may thus advantageously take place when the opening 108a is closed.

In FIGS. 3 and 4 a pivot plate 250 is illustrated as transport means along the transport path 206 and can be pivoted about a pivot axis 251. The pivot plate 250 is arranged in the channeling-in and channeling-out chamber 205 relative to the channeling device 116 such that the channeling device 116 can be opened or closed in a manner unimpaired by the pivot plate 250 when the pivot plate 250 is brought into a provision position.

The pivot plate 250 has a support structure having support means 235 for substrates 130, by means of which the substrates 130 can be fixed detachably on the support structure. The pivot plate 250, in the region of the holding structure, has at least one recess 252; in the illustration of FIG. 4 three recesses of this type are provided, by means of which a comb-like form of the pivot plate is produced. The opening of the recess 252 extends in the pivot direction of the pivot plate 250 in the event of a pivot movement toward the holding device 135.

The holding device 135 has substrate holding elements 265, which are mushroom-like relative to the base plate 136 of the holding device 135. The recesses 252 make it possible to pivot the pivot plate 250 into the region of the substrate holding elements, wherein shafts 265a of the substrate holding elements 265 are arranged in the recesses 252. Finger elements 252a corresponding to the recesses 252 then lie beside the shafts 265a when the pivot plate is pivoted into the region of the substrate holding elements 265a in order to load or unload the holding device 135.

In order to load the holding device 135 with substrates, a channeling door of the channeling device 116 is opened by means of a lifting device 280 coupled to the channel via a rotary feedthrough 275. The pivot plate 250 is moved from the provision region 205a by means of a pivot movement about the pivot axis 251 into the interior la of the vacuum chamber 1, where the finger elements 252a are located with the substrates 130 in the region of the substrate holding elements 265. The substrate holding elements 265 are relatively low-lying at this moment in time, such that these substrates lie thereabove via their underside. The substrate holding elements 265 are then moved upwardly until they receive the substrates 130 from below. Here, the substrates 130 are detached from the support means 235. The pivot plate 250 is then pivoted back again into the provision region 205a. The substrate receiving elements 265, once the pivot plate 250 has been removed from the region of the holding device 135, can be moved downwardly, in particular until openings, in which the shafts 265a are movable, in the base plate 136 are closed by the substrate holding elements 265. The holding device 135 may be formed as a coating rotor having a main rotor axis 260. The substrate holding elements 265 may also be assigned a planetary gearing 270 and, during the rotation about the main axis of rotation 260, may move in turn in a rotary movement about local axes of rotation.

The apparatus, in particular the plasma device 160 and the movable components, inclusive of components not illustrated, such as pumps and sensors, are controlled and/or regulated by means of a control device. It also goes without saying that corresponding voltage sources are provided in order to adjust the electrical potentials at the upper and/or lower sub-portions 105a, 105b and also the holding device 135 or components thereof.

1. An apparatus for the vacuum treatment of substrates, having a
vacuum chamber having a plasma device
a process chamber and
a holding device for substrates which is arranged in the process chamber below the plasma device, wherein
the process chamber comprises an upper sub-portion having a side wall and a lower sub-portion having a side wall
the upper sub-portion and the lower sub-portion are movable vertically relative to one another
wherein
between the side wall of the upper sub-portion and the side wall of the lower sub-portion, a lower flow path is provided between the inner region of the process chamber and the inner region of the vacuum chamber arranged outside the upper sub-portion
between an upper edge region of the upper sub-portion and a sealing element arranged in an upper part of the inner region of the vacuum chamber, an upper flow path is provided between the inner region of the process chamber and the inner region of the vacuum chamber arranged outside the upper sub-portion,
wherein
the upper sub-portion is movable vertically into a lower position, in which the upper flow path is open
the upper sub-portion is movable vertically into an upper position, in which the upper flow path is closed.

2. The apparatus as claimed in claim 1, wherein the side wall of the upper sub-portion is formed as an upper cylinder ring and the side wall of the lower sub-portion is formed as a lower cylinder ring.

3. The apparatus as claimed in claim 1, wherein the holding device is movable relative to the vacuum chamber.

4. The apparatus as claimed in claim 3, wherein the holding device in an upper position can be loaded with substrates via a substrate channeling device.

5. The apparatus as claimed in claim 4, wherein the holding device has a base plate which forms an intermediate base region in the process chamber.

6. The apparatus as claimed in claim 1, wherein the side wall of the upper sub-portion and/or the side wall of the lower sub-portion is/are manufactured at least in part from a conductive material.

7. The apparatus as claimed in claim 6, wherein the upper sub-portion is electrically insulated with respect to the vacuum chamber.

8. The apparatus as claimed in claim 6, wherein the lower sub-portion is electrically insulated with respect to the vacuum chamber.

9. The apparatus as claimed in claim 6, wherein the upper sub-portion is electrically connected to the vacuum chamber.

10. The apparatus as claimed in claim 6, wherein the lower sub-portion is electrically connected to the vacuum chamber.

11. The apparatus as claimed in claim 1, wherein the receiving device is electrically insulated with respect to the vacuum chamber, the upper sub-portion or the lower sub-portion.

12. The apparatus as claimed in claim 1, wherein the lower sub-portion has a base part, which is connected to the side walls of the lower sub-portion.

13. The apparatus as claimed in claim 1, wherein the channeling device comprises a channeling-in and channeling-out chamber which includes a provision region for providing substrates wherein a transport path for transporting substrates leads from the provision region to the holding device and from the holding device to the provision region.

14. The apparatus as claimed in claim 13, wherein a pivot plate is provided for transport along the transport path between provision region and holding device and can be pivoted about a pivot axis between the provision region and holding device.

15. The apparatus as claimed in claim 14, wherein the pivot plate has a support structure having support means for substrates.

16. The apparatus as claimed in claim 15, wherein the holding device has substrate holding elements, wherein the pivot plate in the region of the holding structure has at least one recess, which is associated with the substrate holding elements and allows the pivot plate to be pivoted into the region of the substrate holding elements without any impairment of movement.

17. The apparatus as claimed in claim 16, wherein the substrate holding elements are height-adjustable in order to receive the substrates and to transfer the substrates.

18. The apparatus as claimed in claim 17, wherein the receiving device is formed as a coating rotor having a main axis of rotation.

19. The apparatus as claimed in claim 1, wherein the plasma source is formed as a sputter cathode, electron beam evaporator, or plasma polymerization source.
